(19) United States
(12) Patent Application Publication
(10) Pub. No.: US 2006/0286730 A1
(43) Pub. Date: Dec. 21, 2006

(54) Semiconductor structure and method for forming thereof

(76) Inventors: Yi-Cheng Liu (Alex Liu), Taipei City (TW); Jiunn-Ren Hwang, Hsinchu City (TW); Wei-Tsun Shiau, Meinong Township (TW)

Correspondence Address: J C PATENTS, INC., 4 VENTURE, SUITE 250, IRVINE, CA, 92618, US

(21) Appl. No.: 11/154,377

(22) Filed: Jun. 15, 2005

(51) Int. Cl. H01L 21/8234; H01L 21/336

(52) U.S. Cl. 438/197; 438/305; 438/300; 438/301

(57) ABSTRACT

A semiconductor structure and a method for forming the semiconductor structure are provided. The method for forming a semiconductor structure of the present invention may include the following steps. First, a substrate is provided, wherein a gate is formed over the substrate, and a plurality of offspacers are formed over a sidewall of the gate. Then, a source/drain trench is formed in the substrate at two sides of the gate respectively. Next, an outermost offspacer of the offspacers is removed to expose a flat surface on a surface of the substrate. Thereafter, the source/drain trenches are filled to form a source/drain region. Then, a lightly doped drain (LDD) region is formed in a portion of the substrate under the flat surface.

### BACKGROUND OF THE INVENTION

1. Field of the Invention

The present invention is generally related to a method for forming a semiconductor structure. More particularly, the present invention relates to a semiconductor structure and a method for forming the semiconductor structure.

2. Description of Related Art

Conventionally, the basic transistor structure, such as a metal oxide semiconductor (MOS) transistor has been broadly adopted in a variety of semiconductor devices, such as memory device, image sensor, or liquid crystal display (LCD) panel. Recently, as the semiconductor technology advances, the integration of the semiconductor devices are increased, and thus the line width of the semiconductor device must be reduced. However, a variety of problems arise as the size of MOS structure is reduced.

FIG. 1 is a schematic cross-sectional view illustrating a structure of a conventional MOS transistor. Referring to FIG. 1, the conventional MOS transistor 100 includes a substrate 102, an oxide layer 104, a gate 106, a source 108 and a drain 110. For an N-type MOS (NMOS) transistor, the substrate 102 includes a P-type substrate and the source 108 and the drain 110 are doped with N-type dopants. Alternatively, for a P-type MOS (PMOS) transistor, the substrate 102 includes an N-type substrate and the source 108 and the drain 110 are doped with P-type dopants. In general, the source 108 and the drain 110 are doped by thermal diffusion method or ion implantation method. The region under the oxide layer 104 and between the source 108 and the drain 110 is represented as a channel region 112, wherein a channel length represents a width of the channel region 112 between the source 108 and the drain 110.

As the line width of the conventional MOS transistor 100 reduces, the reduced channel length also correspondingly leads to a short channel effect due to a reduction in the threshold voltage and an increase in the sub-threshold current. In addition, the shortening of the channel length may also generate hot electron effect due to the increase in the electric field between the source 108 and the drain 110. Therefore, the number of the carriers in the channel region 112 near the drain 110 is increased, and thus an electrical breakdown effect may be generated in the MOS transistor 100. Thus, generally the channel length has to be long enough to prevent a punch through effect. Accordingly, as the size of the MOS transistor 100 reduces, the conventional design is not applicable.

Conventionally, to resolve the problem described above, a lightly doped drain (LDD) method is performed on the MOS transistor. FIG. 2 is a schematic cross-sectional view illustrating a structure of a conventional MOS transistor having a lightly doped drain (LDD) structure. Referring to FIG. 2, except for the basic structure of the 1 MOS transistor 100 illustrated in FIG. 1, the MOS transistor 200 further includes a lightly doped source region 202 and a lightly doped drain region 204. The doping area and dopant concentration of the lightly doped source region 202 and a lightly doped drain region 204 are smaller than that of the source 108 and the drain 110. Therefore, the hot electron effect due to the increase in the electric field between the source 108 and the drain 110 is reduced.

However, a MOS transistor having lightly doped drain (LDD) structure has the following disadvantages. First, the series resistance between the source and the drain is increased due to the dopant concentration of the LDD region is lower. Therefore, the electron mobility during the channel region is reduced, and thus the operation speed of the semiconductor structure including the MOS transistor is also reduced. In addition, the power consumption of the MOS transistor is also increased. Accordingly, a novel MOS transistor and a manufacturing method thereof with high performance are quite desired.

### SUMMARY OF THE INVENTION

Therefore, the present invention is directed to a method for forming a semiconductor structure for increasing the electron mobility during the channel region. Therefore, the turn-on and turn-off current and the operation speed of the semiconductor structure are improved, and the performance of the semiconductor structure is also improved.

In addition, the present invention is also directed to a semiconductor structure wherein the electron mobility during the channel region is increased. Therefore, the turn-on and turn-off current and the operation speed of the semiconductor structure are improved, and the performance of the semiconductor structure is also improved.

The method for forming a semiconductor structure of the present invention may comprise the following steps. First, a substrate is provided, wherein a gate is formed over the substrate, and a plurality of offspacers are formed over a sidewall of the gate. Then, a source/drain trench is formed in the substrate at two sides of the gate respectively. Next, an outermost offspacer of the offspacers is removed to expose a flat surface on a surface of the substrate. Thereafter, the source/drain trenches are filled to form a source/drain region. Then, a lightly doped drain (LDD) region is formed in a portion of the substrate under the flat surface.

In one embodiment of the present invention, a material of the source/drain region may comprise a silicon germanium (SiGe) or an epi-silicon germanium (epi-SiGe).

In one embodiment of the present invention, the LDD region is further formed in a portion of the substrate under the offspacers.

In one embodiment of the present invention, a sidewall of the source/drain region adjacent to the offspacers are substantially perpendicular to the surface of the substrate.

In another embodiment of the present invention, a sidewall of the source/drain region adjacent to the offspacers is convex.

In one embodiment of the present invention, a surface of the source/drain region is substantially smooth.

In one embodiment of the present invention, a surface of the source/drain region is convex.

In one embodiment of the present invention, during the substrate is provided, an oxide layer may be further formed between the gate and the substrate.

In one embodiment of the present invention, after the LDD region is formed, an external spacer may be further formed over the offspacers, and the source/drain region may be implanted.

The semiconductor structure of the present invention may comprise, for example, a substrate, two flat surface, a source/drain region and two lightly doped drain (LDD) regions. The substrate may comprise a gate over the substrate, and a plurality of offspacers over a sidewall of the gate. The two flat surfaces may configure over two surfaces of the substrate beside two edges of the spacers. The source/drain region may be in a portion of the substrate beside the two flat surfaces, respectively. In addition, the two LDD regions may be in a portion of the substrate under the flat surfaces.

In one embodiment of the present invention, a material of the source/drain region comprises a silicon germanium (SiGe) or an epi-silicon germanium (epi-SiGe).

In one embodiment of the present invention, the LDD regions are further in a portion of the substrate under the offspacers.

In one embodiment of the present invention, a sidewall of the source/drain region adjacent to the offspacers are substantially perpendicular to the surface of the substrate.

In one embodiment of the present invention, a sidewall of the source/drain region adjacent to the offspacers are convex.

In one embodiment of the present invention, a surface of the source/drain region is substantially smooth.

In one embodiment of the present invention, a surface of the source/drain region is convex.

In one embodiment of the present invention, an oxide is further disposed between the gate and the substrate.

In one embodiment of the present invention, the semiconductor structure may comprise a metal-oxide semiconductor (MOS) device.

In one embodiment of the present invention, a material of the gate may comprise a polysilicon material or a metal material.

In one embodiment of the present invention, a material of the offspacer or a material of the external spacer may comprise a dielectric material, a polymer material, a silicon oxide layer or a silicon nitride layer.

Accordingly, in the present invention, since one offspacer is used as a sacrifice offspacer for providing the flat surfaces on the substrate beside the gate, the portion of the substrate under flat surfaces may be provided for forming the LDD region. In addition, since the source/drain region comprises, for example, silicon germanium (SiGe), and the atom size of germanium is larger than that of silicon, the channel region and the LDD region may be pushed by the source/drain region. Therefore, the electron mobility during the channel region is enhanced, and the turn-on and turn-off current and the operation speed of the semiconductor structure are improved. Accordingly, the performance of the semiconductor structure is also improved.

Accordingly, in the present invention, a multi-step etch method (e.g., including an isotropic step and an anisotropic etch step) is provided. Therefore, the generation of the abnormal material layer along the sidewall of the offspacer may be prevented. Thus, a short between the abnormal material layer and the source or drain may be avoided. In addition, the electron mobility in the channel region is enhanced. Therefore, the series resistance between the source and the drain and the power consumption are also reduced drastically.

One or part or all of these and other features and advantages of the present invention will become readily apparent to those skilled in this art from the following description wherein there is shown and described a preferred embodiment of this invention, simply by way of illustration of one of the modes best suited to carry out the invention. As it will be realized, the invention is capable of different embodiments, and its several details are capable of modifications in various, obvious aspects all without departing from the invention. Accordingly, the drawings and descriptions will be regarded as illustrative in nature and not as restrictive.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view illustrating a structure of a conventional MOS transistor.

FIG. 2 is a schematic cross-sectional view illustrating a structure of a conventional MOS transistor having a lightly doped drain (LDD) structure.

FIG. 3A to FIG. 3I are schematic cross-sectional views illustrating a process flow of manufacturing a semiconductor structure according to one embodiment of the present invention.

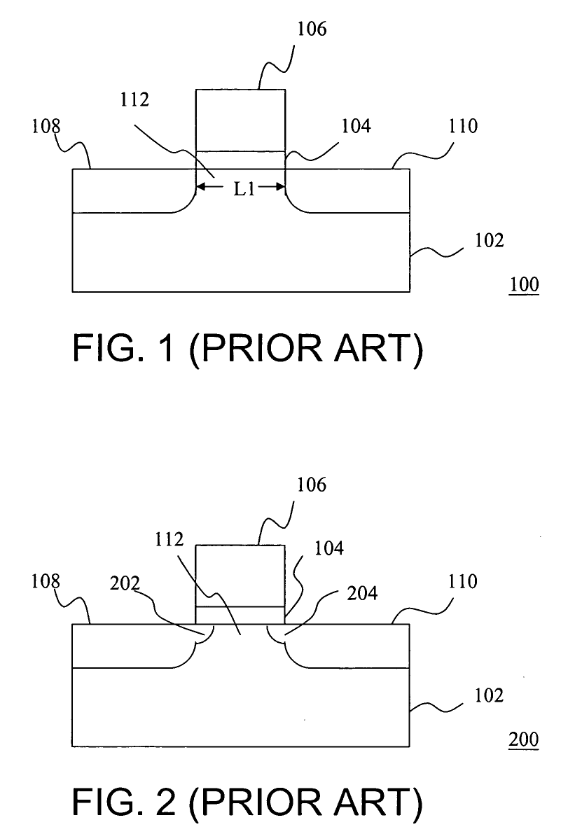

### DESCRIPTION OF THE EMBODIMENTS

The present invention now will be described more fully hereinafter with reference to the accompanying drawings, in which preferred embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art. Like numbers refer to like elements throughout.

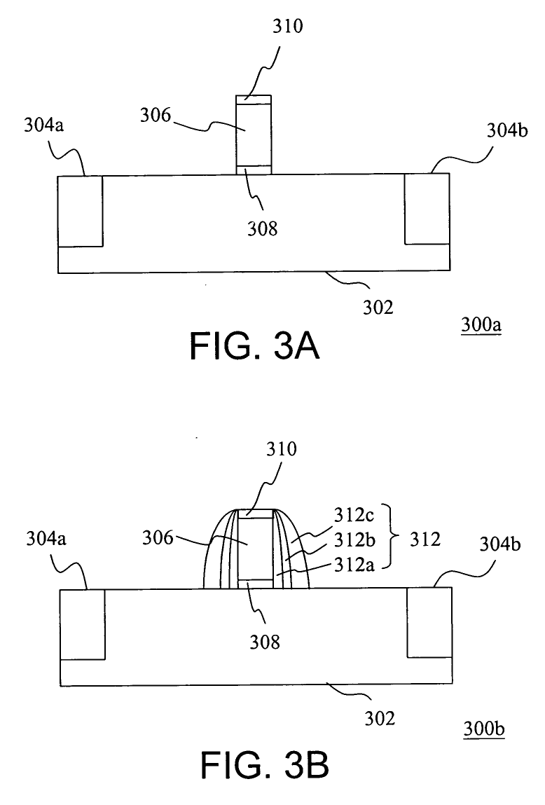

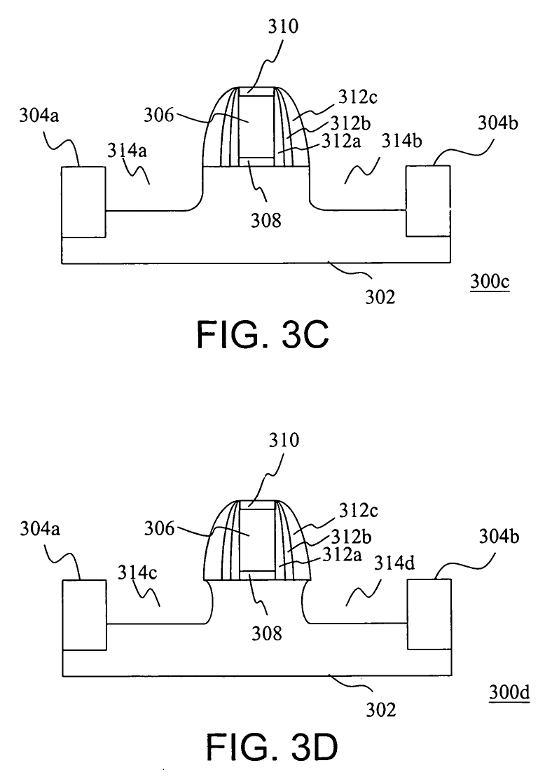

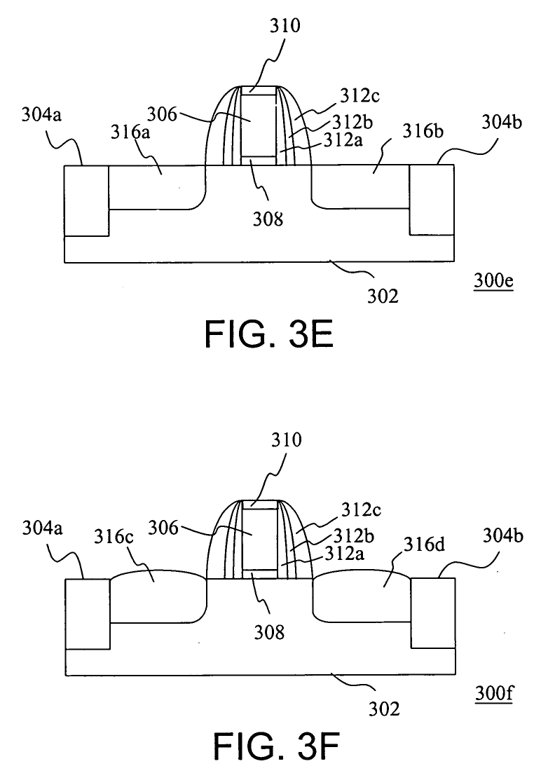

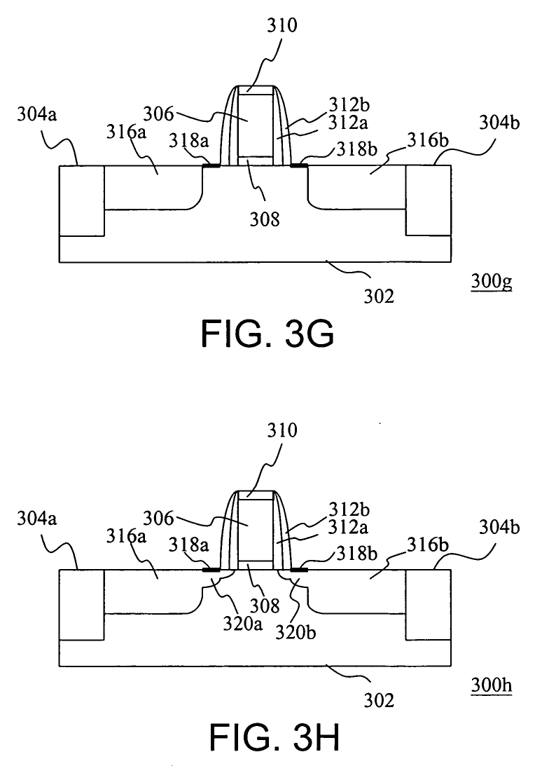

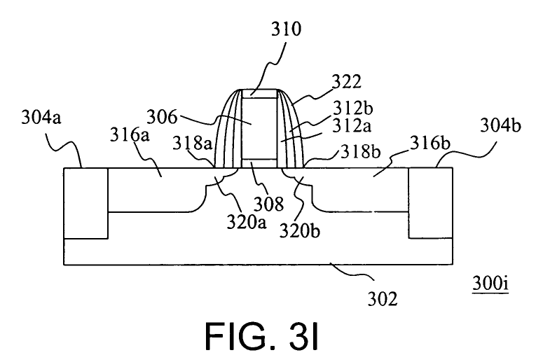

FIG. 3A to FIG. 3I are schematic cross-sectional views illustrating a process flow of manufacturing a semiconductor structure according to one embodiment of the present invention. Referring to FIG. 3A, a semiconductor structure 300a may be formed by, for example but not limited to, the following steps. First, a substrate 302 is provided. The substrate 302 may comprise a silicon substrate. In one embodiment of the present invention, the isolation structures 304a and 304b may also be formed for isolating each semiconductor structure. The isolation structures 304a and 304b may comprise a shallow trench isolation (STI) structure. Thereafter, a gate 306 may be formed over the substrate 302. The material of the gate 306 may comprise metal or polysilicon. In one embodiment of the present invention, a thin layer 308 may be further formed between the gate 306 and the substrate 302, or a cover layer 310 may be further formed over the gate 306. The thin layer 308 may comprise an oxide layer comprising, for example, silicon oxide. The thickness of the gate 306, the thin layer 308 or the cover layer 310 is not limited in the present invention.

Referring to FIG. 3B, offspacers 312a, 312b and 312c, collectively referred as offspacer 312, may be formed over the sidewall of the gate 306. The material of the offspacers 312a, 312b and 312c may comprise a dielectric material, polymer material, silicon oxide or silicon nitride. The thickness of the offspacer 312c may be, for example, between about 0.1 nm to about 30 nm, and preferably between about 0.1 nm to about 10 nm. It should be noted that, in the present invention, the number of the spacers are not limited to three; two or more offspacers may be adopted for the present invention.

Referring to FIG. 3C, source/drain trenches 314a/314b may be formed in the substrate 302 at two sides of the gate 306 by performing, for example, an etching step. As shown in FIG. 3C, the sidewall of the source/drain trenches 314a/314b adjacent to the edge of the offspacer 312c may be substantially perpendicular to the surface of the substrate 302. The depth of the source/drain trenches 314a/314b is not limited in the present invention. In another embodiment of the present invention, the sidewall of the source/drain trenches 314c/314d adjacent to the edge of the offspacer 312c may also be convex due to an over-etch step as shown in FIG. 3D. It should be noted that, the semiconductor structure 300c or 300d shown in FIG. 3C or 3D may be adopted for the following steps of the present invention; therefore, only the semiconductor structure 300c are presented as an exemplary example hereinafter.

Referring to FIG. 3E, the source/drain trenches 314a/314b are filled to form source/drain regions 316a/316b. In one embodiment of the present invention, the material of the source/drain regions 316a/316b may comprise silicon germanium (SiGe). In another embodiment of the present invention, the source/drain regions 316a/316b may be formed by, for example, epi growth process, and thus the material of the source/drain regions 316a/316b may comprise epi-silicon germanium (epi-SiGe). Optionally, in another embodiment of the present invention, the source/drain regions 316a/316b may also be doped in-situ during the process. In yet another embodiment of the present invention, the source/drain regions 316a/316b may be formed by silicon carbide (SiC), for example, to create tensile strain on a NMOS channel or a compressive strain on a PMOS channel. As shown in FIG. 3E, the surface of the source/drain regions 316a/316b may be, for example, smooth. In another embodiment of the present invention, the surface of the source/drain regions 316a/316b may also be, for example, convex ad shown in FIG. 3F. It should be noted that, the semiconductor structure 300e or 300f shown in FIG. 3E or 3F may be adopted for the following steps of the present invention; therefore, only the semiconductor structure 300e are presented as an exemplary example hereinafter.

Referring to FIG. 3G, the outer most offspacer 312c are removed to adjust the overall thickness of the offspacer 312, and thus, flat surfaces 318a/318b represented as bold lines are exposed.

Referring to FIG. 3H, lightly doped drain (LDD) regions 320a/320b may be formed under the flat surfaces 318a/318b. In addition, the LDD regions 320a/320b may be further formed under the offspacers 312a or 314b.

Accordingly, in the present invention, since the offspacer 312c are formed for providing the flat surfaces 318a/318b on the substrate 302, the offspacer 312c may also be represented as a sacrificial spacer. Therefore, the portion of the substrate 302 under flat surfaces 318a/318b may be provided for forming the LDD regions 320a/320b. In addition, the source/drain trenches 314a/314b are refilled with, for example, silicon germanium (SiGe) to form the source/drain regions 316a/316b. Since the atom size of germanium is larger than that of silicon, the channel region (i.e., the portion of the substrate 302 under the thin layer 308) and the LDD regions 320a/320b may be pushed by the source/drain regions 316a/316b. In one embodiment of the present invention, the channel region of the semiconductor structure 300i may be represented as a strained channel region due to the stress from the source/drain regions 316a/316b. Therefore, the electron mobility during the channel region is enhanced, and the turn-on and turn-off current and the operation speed of the semiconductor structure 300h are improved. Accordingly, the performance of the semiconductor structure 300h may also be improved drastically.

Referring to FIG. 3I, a spacer 322 may be formed over the offspacer 312b. In one embodiment of the present invention, the material of the spacer 322 may comprise silicon nitride. Thereafter, the source/drain regions 316a/316b may be implanted. Then, the semiconductor structure 300i may be annealed. In one embodiment of the present invention, the semiconductor structure 300i may comprise a metal-oxide semiconductor (MOS) device. Additionally, in one embodiment of the present invention, the process after the semiconductor structure 300i shown in FIG. 3I may be any practicable or conventional semiconductor process.

In addition, the present invention also provides a semiconductor structure. The semiconductor structure may be, for example, manufactured by the method of the present invention described above. In one embodiment of the present invention, the semiconductor structure as shown in the figures of the invention may comprise, for example, a substrate, two flat surface, a source/drain region and two LDD regions. The substrate may comprise a gate over the substrate, and a plurality of offspacers over a sidewall of the gate. The two flat surfaces may be over two surfaces of the substrate beside two edges of the spacers. The source/drain region may be in a portion of the substrate beside the two flat surfaces respectively. In addition, the two LDD regions may be in a portion of the substrate under the flat surfaces. It is noted that, the characteristics of the semiconductor structure are similar or same as the description described above and will not be repeated again.

Accordingly, in the present invention, since one offspacer is used as a sacrifice offspacer for providing the flat surfaces on the substrate beside the gate, the portion of the substrate under flat surfaces may be provided for forming the LDD region. In addition, since the source/drain region comprises, for example, silicon germanium (SiGe), and the atom size of germanium is larger than that of silicon, the channel region and the LDD region may be pushed by the source/drain region. Therefore, the electron mobility during the channel region is enhanced, and the turn-on and turn-off current and the operation speed of the semiconductor structure are improved. Accordingly, the performance of the semiconductor structure is also improved.

The foregoing description of the preferred embodiment of the present invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

What is claimed is:

1. A method for forming a semiconductor structure, comprising:
providing a substrate, wherein a gate is formed over the substrate, and a plurality of offspacers are formed over a sidewall of the gate;
forming a source/drain trench in the substrate at two sides of the gate respectively;
removing an outermost offspacer of the offspacers to expose a flat surface on a surface of the substrate;
filling the source/drain trenches to form a source/drain region; and
forming a lightly doped drain (LDD) region in a portion of the substrate under the flat surface.

2. The method of claim 1, wherein a material of the source/drain region comprises a silicon germanium (SiGe), an epi-silicon germanium (epi-SiGe) or silicon carbide (SiC).

3. The method of claim 1, wherein the LDD region is further formed in a portion of the substrate under the offspacers.

4. The method of claim 1, wherein a sidewall of the source/drain region adjacent to the offspacers are substantially perpendicular to the surface of the substrate.

5. The method of claim 1, wherein a sidewall of the source/drain region adjacent to the offspacers is convex.

6. The method of claim 1, wherein a surface of the source/drain region is substantially smooth.

7. The method of claim 1, wherein a surface of the source/drain region is convex.

8. The method of claim 1, wherein an oxide layer is further formed between the gate and the substrate.

9. The method of claim 1, wherein after the LDD region is formed, further comprising:
forming an external spacer over the offspacers; and
implanting the source/drain region.

10. A semiconductor structure, comprising:
a substrate comprising a gate over the substrate, and a plurality of offspacers over a sidewall of the gate;
two flat surfaces on two surfaces of the substrate beside two edges of the spacers;
a source/drain region in a portion of the substrate beside the two flat surfaces respectively; and
two lightly doped drain (LDD) regions in a portion of the substrate under the flat surfaces.

11. The semiconductor structure of claim 10, wherein a material of the source/drain region comprises a silicon germanium (SiGe), an epi-silicon germanium (epi-SiGe) or silicon carbide (SiC).

12. The semiconductor structure of claim 10, wherein the LDD regions are further disposed in a portion of the substrate under the offspacers.

13. The semiconductor structure of claim 10, wherein a sidewall of the source/drain region adjacent to the offspacers are substantially perpendicular to the surface of the substrate.

14. The semiconductor structure of claim 10, wherein a sidewall of the source/drain region adjacent to the offspacers is convex.

15. The semiconductor structure of claim 10, wherein a surface of the source/drain region is substantially smooth.

16. The semiconductor structure of claim 10, wherein a surface of the source/drain region is convex.

17. The semiconductor structure of claim 10, wherein an oxide layer is further disposed between the gate and the substrate.

18. The semiconductor structure of claim 10, wherein the semiconductor structure comprises a metal-oxide semiconductor (MOS) device.

19. The semiconductor structure of claim 10, wherein a material of the gate comprises a polysilicon material or a metal material.

20. The semiconductor structure of claim 10, wherein a material of the offspacer or a material of the external spacer comprises a dielectric material, a polymer material, a silicon oxide layer or a silicon nitride layer.
